(19) United States
(12) Patent Application Publication
(10) Pub. No.: US 2006/0060796 A1
(43) Pub. Date: Mar. 23, 2006

(54) Method and apparatus for plasma source ion implantation in metals and non-metals

(76) Inventor: Krupakar M. Subramanian, Boise, ID (US)

Correspondence Address: Wilson Daniel Swayze, Jr, 3804 Clearwater Ct, Plano, TX, 75025, US

(21) Appl. No.: 11/220,184

(22) Filed: Sep. 6, 2005

Related U.S. Application Data
(60) Provisional application No. 60/607,271, filed on Sep. 7, 2004.
(60) Provisional application No. 60/607,039, filed on Sep. 3, 2004.

(51) Int. Cl. H01J 37/08

(52) U.S. Cl. 250/492.21

(57) ABSTRACT

Ion Implantation into surfaces of three-dimensional metallic and non-metallic targets is achieved by building a metallic mesh enclosure around the target through rapid-prototyping and then forming an ionized plasma about the target within an enclosing chamber and applying a pulse of high voltage between the wire mesh and the conductive walls of the chamber. The ions from the plasma are driven towards the wire mesh, since the mesh has finite transparency; some of the ions continue to move towards the target and are driven into the target from all sides simultaneously without the need of manipulation of the target object. Repetitive and alternating pulses of high voltages, typically 1 kV or higher, causes the ions to be implanted into the surface of the target. The plasma may be formed of a neutral gas introduced into the evacuated chamber and ionized therein with ionizing radiation so that a constant source of plasma is provided which surrounds the target object during the implantation process. Materials with new surface properties such as increased surface hardness and wear may be generated in this manner. Target object surfaces with sharp features, metals and non-metals can be treated by this technique. This technique would prove helpful in manipulating the surface properties of composites used in building aircrafts, automobiles, ships etc., metallic or non-metallic surfaces with sharp features, and the inner surfaces of tubular objects.

### PRIORITY

The presently claimed invention claims priority based on provisional applications Ser. Nos. 60/607,271 filed on Sep. 7, 2004 and 60/607,039 filed Sep. 3, 2004.

### FIELD OF THE INVENTION

This invention pertains generally to the field of surface treatment and particularly to surface treatment by ion implantation techniques.

### BACKGROUND OF THE INVENTION

Ion implantation offers great commercial promise for the improvement of the surface characteristics of a variety of materials, including metals, ceramic and plastics. In the conventional ion implantation process ions are formed into a beam and accelerated to high energy before being directed into the surface of a solid target. Such ion implantation allows production of materials with new surface properties. In particular, implantation can be used to improve greatly the friction, wear and corrosion resistance properties of the surfaces of both metals and non-metals. For example, the surface properties of metals, ceramic components and ceramic cutting tools can be improved by ion implantation of nitrogen. For a general discussion of the techniques and potential advantages of ion implantation, see generally S. Picraux, et al., “Ion Nitriding and Ion Implantation: A Comparison,” Metal Progress, August 1985, pp. 18-21; V. M. Cassidy, “Ion Implantation Process Toughness Metalworking Tools,” Modern Metals, September 1984, pp. 65-67.

Conventional techniques as described by Conrad in U.S. Pat. No. 4,764,394 describes a unique technique to directly implant metal surfaces with ions from the surrounding plasma, however if the metal surface has sharp features then it causes premature breakdowns in the plasma thus limiting the performance of the device.

While commercially viable applications of conventional ion implantation techniques have been demonstrated, the relatively high cost of the process has limited its use thus far to high unit cost items having special applications, especially for ceramic substrates. A significant problem associated with nonmetallic targets is caused by the charge that quickly builds up around the target as the ions embed on the surface. Such a surface charge prevents further implantation. Furthermore, to get the ions to embed on the surface, an electrode has to be inserted into the target for pulsing. The need to manipulate a three-dimensional target to allow all sides of the target to be implanted adds cost and complexity, constrains the maximum size of the target which can be implanted, and increases the total time required to obtain satisfactory implantation of all target surfaces for any sized targets. Another problem associated with such an ion implantation technique is that depending on the electrode shape ions do not arrive perpendicular to the surface. Normal incidence of ions to the surface is preferred since as the angle of incidence with respect to the normal decreases, sputtering increases and the net retained dose in the target decreases. Hence a new technique is proposed in the present invention to overcome the above limitations and extend the applicability of Plasma source ion implantation technique to various purposes that include the treatment of surfaces of the metal objects with sharp edges, and non-metallic surfaces.

### SUMMARY

The following presents a simplified summary of the invention in order to provide a basic understanding of some aspects of the invention. This summary is not an exhaustive overview of the invention Its sole purpose is to present some concepts in a simplified form as a prelude to the more detailed description that is discussed later.

The present invention provides significantly improved production efficiencies in ion implantation of three-dimensional materials by achieving implantation of the target from all sides of the target simultaneously. Consequently, the production efficiency for implantation of three-dimensional objects is greatly increased over conventional ion implantation techniques. Since an electrode need not be inserted inside the target, and complicated target manipulation is not required.

In accordance with the present invention, which may be denoted plasma source ion implantation for nonmetals, the target to be implanted is surrounded by a substantially transparent enclosure (hereafter referred to as ‘enclosure’) specifically manufactured for a given target within an evacuated chamber. Such enclosures can be manufactured using any of the already available techniques such as rapid-prototyping. The plasma is generated within the chamber through any of the available techniques such as capacitively or inductively coupled plasma generator, magnetron ionization source, microwave ionization source, electromagnetic ionization source (e.g., Ultraviolet rays, X-rays etc.) and through electron impact ionization. For instance, the electrons for the impact ionization may be generated using filament electron sources. A high negative potential pulse is then applied to the enclosure relative to the walls of the chamber to accelerate ions from the plasma across the plasma sheath towards the enclosure in directions substantially normal to the surfaces of the wire mesh (used in the construction of the enclosures) at the points where the ions impinge upon the surface of the wire mesh. Since the enclosure is transparent (typically 85% or higher), most ions continue to move towards the target and get embedded on its surface. A positive charge builds up on the surface of the target quickly and hence a positive pulse is then applied to the enclosure to accelerate electrons from the plasma towards the target that neutralizes the positive charge on the surface of the target. Repeated application of positive and negative pulses to the enclosure will result in implantation of ions on the surface of the target in sufficient quantities until the desired concentration of implanted ions within the target object is achieved.

Preferably, the ion source plasma surrounding the target object is formed by introducing the ion source material in the gas or vapor form into the highly evacuated space within the confining chamber. The gaseous material may then be ionized by directing ionizing radiation, such as a diffuse beam of electrons, through the source gas in a conventional manner. Consequently, a plasma of ions is formed which completely surrounds the target object and the enclosure so that ions may be implanted into the target from all sides, if desired. Multiple targets with dedicated enclosures, properly spaced within the plasma, may be implanted simultaneously in accordance with the invention. Another technique to generate plasma around the target is to use either a single or multiple number of grids to which the radio frequency (RF) signal is applied. Such grids may be either spherical or is shaped such that the enclosure is substantially similar to the object being implanted. This kind of enclosure shaping will surround the target object predominantly uniformly.

Utilizing the ion implantation process and apparatus of the present invention, ion implantations may be performed on complex, three-dimensional objects formed of a great variety of materials, including pure metals, alloys, semi-conductors, ceramics, and organic polymers. Significant increases in surface hardness are obtained with ion implantation of a variety of source materials, including gases such as nitrogen, into metal and ceramic surfaces. Ion implantation of organic plastic materials can produce desirable surface characteristic modifications including a change in the optical properties and the electrical conductivity of the polymer. Ion implantation is also found to be particularly beneficial when used in conjunction with conventional heat treatment hardening techniques. Metal objects, which have been both ion implanted in accordance with the present invention, and heat-treated are found to exhibit significantly greater hardness and resistance to wear than objects which are only heat treated or ion implanted, but not both.

A significant advantage of the present technique over the other earlier techniques is the ability to work with surfaces that have sharp features. The enclosure protects the metallic target objects from the high voltage breakdown problems thus helping achieve the desired ion current densities and energies for ion implantation purposes.

### BRIEF DESCRIPTION OF THE DRAWINGS

The invention may be understood by reference to the following description taken in conjunction with the accompanying drawings, in which, like reference numerals identify like elements, and in which:

FIG. 1 illustrates an ion implantation apparatus;

FIG. 2 illustrates a target and the enclosure;

FIG. 3 illustrates a symmetrically shaped object and a conductive enclosure.

FIG. 4 illustrates an asymmetrically shaped object and a conductive enclosure.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed.

### DETAILED DESCRIPTION

This disclosure of the invention is submitted in furtherance of the constitutional purposes of the U.S. Patent Laws “to promote the progress of science and useful arts” (Article 1, Section 8).

Illustrative embodiments of the invention are described below. It will course be appreciated that in the development of any such actual embodiment, numerous implementation-specific decisions must be made to achieve the developers' specific goals, such as compliance with system-related and business-related constraints, which will vary from one implementation to another. The present invention will now be described with reference to the attached figures. Additionally, the relative sizes of the various features and structures depicted in the drawings may be exaggerated or reduced as compared to the actual size of those features or structures. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

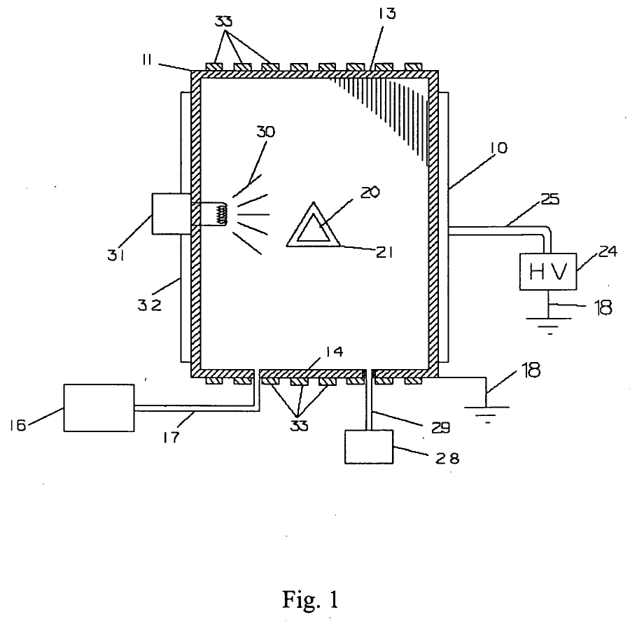

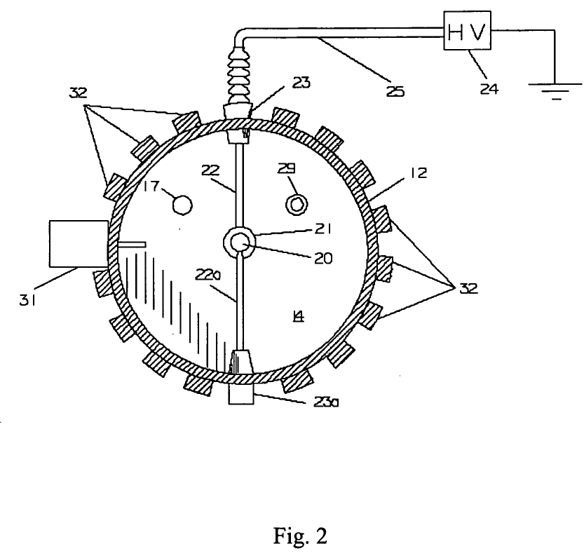

With reference to the drawings, an ion implantation apparatus in accordance with the present invention is shown generally at 10 in partial cross-section in FIG. 1. The apparatus 10 includes an enclosing chamber 11 having conductive walls, e.g., of stainless steel or aluminum, which may be formed, as shown, with an outer cylindrical wall 12 shown in FIG. 2, a top wall 13 which may be flat and a bottom wall 14 which may be flat. A vacuum pump 16 is connected by an exhaust line 17 to the interior of the chamber and operates to evacuate the chamber to a very low base pressure vacuum level (typically on the order of 10⁻⁶ Torr). As explained further below, the operating pressure within the chamber 11 is preferably on the order of 10⁻⁴ Torr. All of the walls 12, 13 and 14 making up the chamber 11 are electrically connected together and connected by a line 18 to ground.

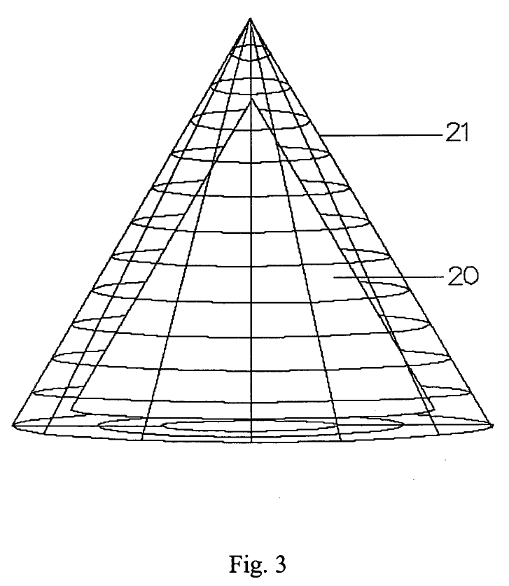

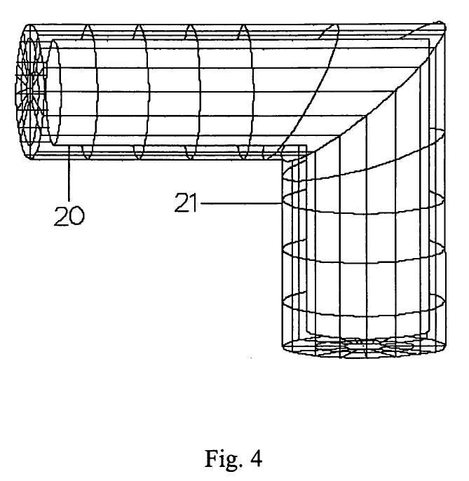

The target object illustratively shown at 20 as a three-dimensional block (for example a cone is shown in FIG. 3) is mounted substantially in the middle of the interior of the chamber 11, spaced away from all of the walls 12, 13, and 14 of the chamber at the end of a nonconductive support arm 22. Of course, the target 20 may assume a variety of shapes, including shapes having indentations and cavities. The target 20 is surrounded by a conducting enclosure 21 (also see FIG. 2) held in position by a conductive support arm 22. An intermediate holding device (not shown in the figure) may be used to easily install and remove either the target or the enclosure on the arms. The target 20 may be mounted on and removed from the arm 22a through a door (not shown) formed in the cylinder wall 12 which, when closed, seals airtight to the wall and is also electrically connected to the walls to be at the same potential as the walls. FIG. 4 illustrates an asymmetrically shaped target 20 and the corresponding enclosure 21. The enclosure 21 can be opened at, at least one point to enable the asymmetrical object be placed within the enclosure and then sealed. The size and shape of the enclosure is substantially similar to the target asymmetrical object, only that it is bigger. The spacing between such enclosures shown in both FIG. 3 and FIG. 4 should have enough spacing to allow at least some amount of motion to the target object being implanted. The oscillatory or rotational motion induced on to the objects ensures that the target object is substantially evenly implanted and ensures that the wires of the enclosure do not screen the target object. Since the enclosures are intended to have openings that will allow the placement of the object into the enclosure, each enclosure can be used multiple number of times with a plurality of objects of similar dimensions. The material used for the construction of such enclosures could be stainless steel, tungsten, rhenium, molybdenum, nickel, chromium, platinum, gold, silver, iron, graphite, etc. and alloys thereof. Also, it is understood that a matching network will be used where RF power is used to maximize the performance of the device.

It is a particular advantage of the present invention that target objects with a variety of complex shapes can be ion implanted, however each of the targets 20 would require preferably a dedicated enclosure, a single enclosure can be used multiple number of times with similar targets. The need for a complex manipulation of either an ion beam or the target as required in conventional line of sight ion implantation is not required, thereby eliminating the need for the conventional ion accelerator stage, raster scan apparatus and target manipulator. Also, no electrode is inserted into the target (for target biasing) and hence complex target manipulations are not required. The arm 22 holds the enclosure 23a in a fixed position by a conductive clamp (not shown) on the stage 21.

The arm may be covered with electrical insulation, if desired, or even shielded so that ions are not attracted to the arm. In addition, the support arms 22 and 22a may also be formed so that a coolant fluid is circulated through it to allow thermodynamic cooling of the target 20 during the ion implantation process to maintain the target in substantial thermal equilibrium. Cooling of the target during implantation is desirable to minimize the thermal diffusion of ions away from the target surface. The conductive support arm 22 is electrically isolated, by an insulator 23, from the cylindrical wall 12 of the chamber through which it passes, and the insulator 23 is also formed to provide an air-tight seal to the wall 12 of the chamber. The nonconductive arm 22b is connected to a motor 22b through an airtight seal to the wall 12. A high voltage, pulse power supply 24 is used to provide the high voltage through a supply line 25 to the conductive support arm 22. The supply 24 provides repetitive pulses of high voltage, e.g., in the 5 kV to 3 MV range, of duration selected as described below. For example, the high voltage supply may be of the pulse line-pulse transformer type providing pulse lengths in the range of a few microseconds, or the supply may be chosen from various types of high voltage tube modulated pulses capable of providing relatively long pulse lengths at least in the milliseconds range.

In accordance with this invention, ionized plasma is generated which surrounds the enclosure 23a within the chamber 11 so that ions may be accelerated into the target from all sides. To generate the surrounding plasma, where a gas is to be used as the material to be implanted, a gas source 28 is connected by a line 29 to leak the gas at a low, controlled rate into the chamber 11 as it is being evacuated by the vacuum pump 16. Prior to ionization, there thus will be a low pressure atmosphere of the gas from the gas source 28 within the chamber 11 mixed with very low levels of other impurity gases such as oxygen, etc. For purposes of illustration, the following description will assume that a source of nitrogen gas is provided from the gas source 28, although it will be apparent that many other sources of ionizing ambient may be provided by the vaporization of liquids and solids to form the ambient gas. The neutral gas within the chamber may be ionized in various ways. One method illustrated in FIGS. 1 and 2 is the injection into the chamber of a diffuse beam of electrons 30 from a heated filament electron source 31. The beam of electrons from the source 31 spreads through the interior of the chamber 11, colliding with the neutral gas to form ions. To maximize the collisions between the electrons ejected from the source 31 and the ambient gas, magnet bars 32 are distributed about the outer periphery of the cylindrical side wall 12 of the chamber and magnetic pellets 33 are distributed over the top wall 13 and bottom wall 14. Adjacent magnet bars 32 are oppositely poled i.e., alternating north to south to north, etc., so that magnetic lines of force run between adjacent magnet bars within the interior of the chamber. Similarly, adjacent magnetic pellets 33 on the top and bottom walls of the chamber are oppositely poled so that magnetic lines of force run into the chamber between these pellets. The magnetic field thus formed around the interior of the chamber adjacent to the walls of the chamber causes electrons from the electron source to turn around as they approach the wall and move back into the interior of the chamber, where they may collide with gas atoms or molecules to ionize the gas.

Similarly other ionization sources such as a magnetron, electron cyclotron resonance heating system, microwave horn antennas etc., and any combination thereof may be used for ionizing the ambient gases within the chamber 11. Utilizing a multi-dipole filament discharge electron source 31 at an operating pressure in the range of approximately 10⁻⁶ to 10⁻³ Torr, satisfactory plasmas are formed having a density of 10⁶ to 10¹¹ ions per cubic centimeter with an electron temperature of a few electron volts and an ion temperature of less than one electron volt. In one embodiment of the invention sources of ionizing electromagnetic radiation (e.g., ultraviolet light, X-rays etc.,) may be utilized to ionize the gas within the chamber 11 to form plasma, which surrounds the target object.

In one embodiment of the invention the ionization of the ambient gas within the chamber 11 is produced by RF power applied to another electrically isolated enclosure (not shown in the figures) placed around the enclosure 23a with respect to ground. Provisions have to be made to electrically connect such a source with the RF power supply placed outside the chamber, while simultaneously isolating it from the rest of the apparatus 10.

In another embodiment of the invention the ionization is provided by applying the RF power to a coil that is placed either substantially outside the chamber surrounding it or inside the chamber surrounding the target. In either case such an electric coil would have to be isolated from the rest of the apparatus 10.

In another embodiment of this invention, the enclosure is placed inside an object and the plasma is generated inside the enclosure and the ions are accelerated outwards. These ions implant on the inner surfaces of the object. One way to generate the plasma for such applications would be to use another enclosure like material but of smaller dimensions and subsequently applying RF power to it. In another embodiment of this invention an electron gun is used to generate plasma within the enclosure.

In another embodiment of the invention minute (e.g., nanoparticles) particles are dropped into the chamber with plasma in it and/or are subsequently ionized using the electrons from the filament electron source. These charged particles are then accelerated by the enclosure on to the target's outer and/or inner surfaces.

A great variety of materials can be used as the target objects 20 for ion implantation in this manner, including pure metals and alloy metals such as steel, semiconductors, ceramics, organic polymers etc. Any type of the various plasma sources for ion implantation may be utilized as the source of the ions to be implanted, with these ions being introduced into the chamber 11 to form plasma, which substantially surrounds the target object. These include gases such as nitrogen, oxygen, hydrogen, noble gases, fluorocarbons, hydrocarbons, vapors of solids, vapors of fluids and any mixture combination thereof. For example, evaporation of boron and/or carbon layers on to a substrate such as Al₂O₃ followed by implantation with nitrogen ions.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention.

Hence, it is to be understood, however, that the invention is not limited to the specific features shown and described, since the means herein disclosed comprise preferred forms of putting the invention into effect. The invention is, therefore, claimed in any of its forms or modifications within the proper scope of the appended claims. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention

What is claimed is:

1) An ion implantation apparatus, comprising:
a chamber for implanting ions,
a vacuum pump and a gas supply to maintain the chamber environment;
a ionization source for generating said implanting ions.
a target for implanting said ions, and
a conducting enclosure for enclosing said target and for accelerating said implanting ions to said target.

2) An ion implantation apparatus as in claim 1, wherein said ionization source includes at least one heated filament.

3) An ion implantation apparatus as in claim 1, wherein said ionization of the ambient gases in the said chamber is produced by the RF power applied to at least one conducting component of the said chamber.

4) An ion implantation apparatus as in claim 1, wherein said ionization of the ambient gases within the said chamber is produced by the RF power applied to at least one conducting coil placed close to the target inside the said chamber.

5) An ion implantation apparatus as in claim 1, wherein said ionization of the ambient gases in the said chamber is produced by the RF power applied to at least one conducting coil placed outside the said chamber.

6) An ion implantation apparatus as in claim 1, wherein said chamber is made of at least one of the materials—stainless steel, aluminum, copper, glass, quartz, sapphire, silicon, rubber, ceramic, plastic, lexan, and organic polymers.

7) An ion implantation apparatus as in claim 1, wherein said enclosure is subject to at least one voltage with respect to the ground potential.

8) An ion implantation apparatus as in claim 1, wherein said chamber includes a magnet to generate said magnetic fields to enhance ionization of the ambient gas within the said chamber.

9) An ion implantation apparatus as in claim 1, wherein at least one arm holds said target and the said enclosure.

10) An ion implantation apparatus as in claim 9, wherein said apparatus includes a power supply to provide power to said arm.

11) An ion implantation apparatus as in claim 1 wherein said apparatus includes a vacuum pump to evacuate said chamber.

12) An ion implantation apparatus as in claim 1, wherein said apparatus includes a gas source to impart gas to said chamber.

13) An ion implantation apparatus as in claim 12, wherein said apparatus includes a vacuum pump to evacuate the chamber, and wherein said gas is generated while said vacuum pump actuates the chamber.

14) An ion implantation apparatus as in claim 9, wherein said arm is insulated and/or shielded.

15) A method for ion implantation, comprising the steps of:
forming a chamber for implanting ions;
generating said implanting ions;
enclosing said target with at least partially conducting enclosure;
attracting said implanting ions to a target;
accelerating said implanting ions through said conducting enclosure;
accelerating electrons through said conducting enclosure;
moving said enclosure with respect to the target;
accelerating said implanting ions through said conducting enclosure.
accelerating electrons through said conducting enclosure;

16) A method for ion implantation as in claim 15, wherein said method includes the step of placing the target on a conducting platform with the said enclosure held close to the target by said arm.

17) A method for ion implantation as in claim 15, wherein said method includes the step of providing power to the said arm.

18) A method for ion implantation as in claim 15, wherein the said enclosure covers at least a portion of the said target.

19) A method for ion implantation as in claim 15, wherein the said enclosure can be opened at least at one point to insert the target into the said enclosure.

20) A method for ion implantation as in claim 15, wherein the said enclosure is held at least 1 mm away from the surface of the said target.

21) A method for ion implantation as in claim 15, wherein the said enclosure is moved with respect to the target by said arm.

22) A method for ion implantation as in claim 15, wherein the said enclosure is placed inside an object to accelerate ions outwards from the said enclosure to implant the inner surfaces of the said object.

23) A method for ion implantation as in claim 15, wherein the plasma is generated inside the said enclosure using at least one of the ionization sources such as electron beam, filament electron source, RF power applied to at least one other grid or coil placed inside the said enclosure.

24) A method for ion implantation as in claim 15, wherein the said ions are charged particles in the size range of 1 nm to 100 μm.
